(19) United States
(12) Patent Application Publication
(10) Pub. No.: US 2005/0225470 A1
(43) Pub. Date: Oct. 13, 2005

(54) DIGITALLY SELF-CALIBRATING PIPELINE ADC AND CONTROLLING METHOD THEREOF

(76) Inventors: Jui-Yuan Tsai, Tai-Nan City (TW); Wen-Chi Wang, Yun-Lin Hsien (TW); Chia-Liang Chiang, Taipei Hsien (TW); Chao-Cheng Lee, Hsin-Chu City (TW)

Correspondence Address: NORTH AMERICA INTELLECTUAL PROPERTY CORPORATION, P.O. BOX 506, MERRIFIELD, VA, 22116, US

(21) Appl. No.: 10/907,618

(22) Filed: Apr. 8, 2005

(30) Foreign Application Priority Data
Apr. 9, 2004 (TW) 093109956

(51) Int. Cl. H03M 1/38

(52) U.S. Cl. 341/161

(57) ABSTRACT

A pipeline ADC for converting an analog input signal to a digital output signal includes: a plurality of analog-to-digital converting units cascading in series to form a pipeline including a plurality of digital output ends; a calculation unit coupled to the analog-to-digital converting units for generating a plurality of calibration parameters in a first mode according to signals at the digital output ends; and a calibration unit coupled to the calculation unit and the analog-to-digital converting units for calibrating signals at the digital output ends in a second mode according to the calibration parameters, so as to generate the digital output signal.

### BACKGROUND OF INVENTION

1. Field of the Invention

The present invention relates to an analog-to-digital converter (ADC) and a related method, and more particularly, to a digitally self-calibrating pipeline ADC and a controlling method thereof.

2. Description of the Prior Art

A pipeline analog-to-digital converting structure is typical for an analog-to-digital converter (ADC). Without using any trimming or calibration technique either in analog or digital way, the resolution of the pipeline ADC only approaches to a degree of ten to twelve bits due to capacitance mismatch or limited gain of an operational amplifier. Therefore, trimming or calibration technique is required for increasing the resolution of a pipeline ADC, such as the technique disclosed by U.S. patents with patent No. 5,499,027 and 6,369,744.

### SUMMARY OF INVENTION

It is therefore an objective of the claimed invention to provide a digitally self-calibrating pipeline analog-to-digital converter (ADC) and a controlling method thereof to solve the above-mentioned problems.

According to a first aspect of the claimed invention, a pipeline ADC for converting an analog signal to a digital output signal comprises: a plurality of analog-to-digital converting units cascading in series to form a pipeline; a calculation unit for generating a plurality of calibration parameters according to the signals outputted by the analog-to-digital converting units during a first mode; and a correction unit for correcting the signals outputted by the analog-to-digital converting units during a second mode according to the calibration parameters, so as to generate said digital output signal.

According to another aspect of the claimed invention, a method for operating a self-calibrating pipeline ADC which includes a plurality of analog-to-digital converting units cascading in series to form a pipeline comprises: generating a plurality of calibration parameters according to the digital signals outputted by the analog-to-digital converting units, wherein the calibration parameters can be generated in any order; and correcting the digital signals outputted by the analog-to-digital converting units during a second mode according to the calibration parameters.

These and other objectives of the claimed invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a diagram of a digitally self-calibrating pipeline analog-to-digital converter (ADC) according to an exemplary embodiment of the present invention.

FIG. 2 is a diagram of measurement conditions of intermediate error coefficients of the ADC shown in FIG. 1.

FIG. 3 is a diagram of measurement order of intermediate error coefficients of the ADC shown in FIG. 1.

### DETAILED DESCRIPTION

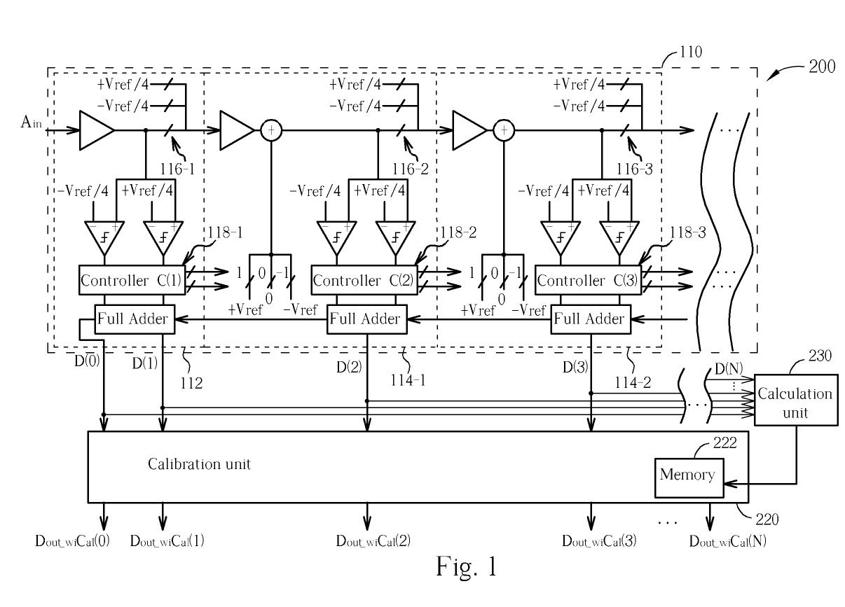

Please refer to FIG. 1, which illustrates a diagram of a digitally self-calibrating pipeline analog-to-digital converter (ADC) 200 according to an embodiment of the present invention. The pipeline ADC 200 comprises a pipeline structure 110. The pipeline structure 110 includes an input stage 112 and a plurality of subsequent stages 114-1, 114-2 . . . . . . . and 1114-N cascading in series. In the following description of the present embodiment, the pipeline structure 110 is implemented as a well-known structure with 1.5 bits/stage. Furthermore, other structures such as structures with 1 bit/stage or multi-bits/stage can be easily applied to the pipeline structure 110 of the present invention by those skilled in the art.

In order to correct output values of the pipeline structure 110 and thereby eliminate errors to obtain accurate output values, the pipeline ADC 200 further comprises a calibration unit 220 coupled to each stage 112, 114-1, 114-2, . . . , and 114-N as shown in FIG. 1. The calibration unit 220 is used for correcting the digital output signal outputted by each stage 112, 114-1, 114-2, . . . , and 114-N during a run mode according to a plurality of calibration parameters [CALA(I), CALB(I)] (I=1, 2 . . . . . . , N) stored in a memory 222.

Besides, in order to obtain the calibration parameters [CALA(I), CALB(I)], the pipeline ADC 200 further includes a calculation unit 230 coupled to each stage 112, 114-1, 114-2, . . . , and 114-N as shown in FIG. 1. The calculation unit 230 is used for reading the digital output value of each stage 112, 114-1, 114-2, . . . , and 114-N during a calibration mode and generating the calibration parameters [CALA(I), CALB(I)] which respectively corresponds to each stage 112, 114-1, 114-2, . . . , and 114-N; meanwhile, fixed values of analog and digital signals are respectively inputted into each stage 112, 114-1, 114-2, . . . , and 114-N. The calibration parameters [CALA(I), CALB(I)] are stored in the memory 222 and used by the calibration unit 220 to correct the digital output value of each stage during the run mode.

In this embodiment, the above-mentioned fixed values include fixed voltage values +Vref/4 and −Vref/4 and fixed signal values C(1), C(2) respectively generated by the controllers as shown in FIG. 1. These fixed values are inputted into each stage 112, 114-1, 114-2, . . . , and 114-N by using a plurality of switches 116-1, 116-2 . . . . . . , 116-N and 118- 1, 118-2 . . . . . . , 118-N. More specifically, during the run mode, all the switches 116-1, 116-2 . . . . . , 116-N and 118-1, 118-2 . . . . . . . , 118-N are switched such that analog and digital signals are transmitted from a preceding stage to a corresponding next stage and thus the pipeline ADC 200 converts an analog signal Ain inputted into the input stage 112 to calibrated digital output values Dout_wiCal(0), Dout_wiCal(1) . . . . . . , Dout_wiCal(N) outputted by the calibration unit 220. Otherwise, during the calibration mode, at least one of the switches is switched such that the above-mentioned fixed values are inputted into a proper stage so that the calculation unit 230 can read the output values of the pipeline structure 110 and generate the calibration parameters, wherein the circuit configurations and operation of the switches 116-1, 116-2 . . . . . . , 116-N and 118-1, 118-2 . . . . . . 1, 118-N are well known in the art.

The operation of the calculation unit 230 is described as follows. In this embodiment, errors of the output values outputted by the fifth and latter stages are assumed to be minor in contrast to those of the other stages such that the influence of these minor errors is negligible. Under this assumption, the output values outputted by the fifth and latter stages have no need to be corrected, and only calibration parameters of the first four stages are necessary to be generated.

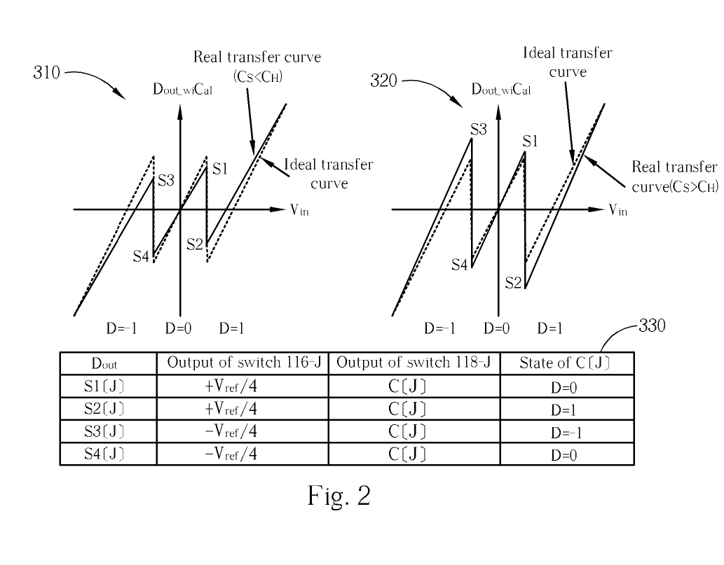

To obtain the calibration parameters, the calculation unit 230 reads a plurality of intermediate error coefficients [ERA(J), ERB(J)] from the pipeline structure 110, wherein the range of the index J depends on the accuracy needed. In this embodiment, the index J varies from 1 to 4. Please refer to FIGS. 1 and 2, the intermediate error coefficients ERA(J) and ERB(J) are generated as ERA(J)=S1 [J]−S2[J]−2\hat{ }A(N−J) and ERB(J)=S3[J]−S4[J]-2\hat{ }A(N−J), and stored in the memory 222, wherein the measurement values S1[J], S2[J], S3[J], and S4[J] are respectively generated under certain measurement conditions as shown in FIG. 2 and each of these values S1[J], S2[J], S3[J], and S4[J] represents a digital output value determined by the output values D(J+1) . . . . . . , D(N) which are respectively outputted by 114-(J+1) stage, 114-(J+2) stage, . . . , and 114-(N) stage during the calibration mode. Physical meanings and measurement conditions of the above-mentioned measurement values S1[J], S2[J], S3[J], and S4[J] are respectively shown in transfer curves 310 and 320 and a condition table 330 in FIG. 2. The transfer curves 310 and 320 represent two possible erroneous conditions, and the above-mentioned physical meanings and the ways to determine the conditions are well known in the art.

After obtain all the necessary intermediate error coefficients ERA(J) and ERB(J), the calculation unit 230 further generates the calibration parameters [CALA(I), CALB(I)]. The calculation for generating the calibration parameters [CALA(I), CALB(I)] can be achieved by using many different algorithms. However, for simplicity, only calculation principles of the calibration parameters [CALA(I), CALB(I)] with I=1, 2 . . . . . . , 6 are described in the following. The calibration parameters of lower stages can be derived from similar principles.

According to a first example of the calculating algorithms, i.e. a bottom-up algorithm, the output values of the fifth and latter stages are assumed to be ideal values and the errors thereof are negligible. Hence, the calibration parameters can be derived using the following equations:
CALA(6)=0
CALB(6)=0
CALA(5)=0
CALB(5)=0
CALA(4)=ERA(4)
CALB(4)=ERB(4)
CALA(3)=ERA(3)+CALA(4)+CALB(4)
=ERA(3)+ERA(4)+ERB(4)
CALB(3)=ERB(3)+CALA(4)+CALB(4)
=ERB(3)+ERA(4)+ERB(4)
CALA(2)=ERA(2)+CALA(3)+CALB(3)
=ERA(2)+ERA(3)+ERB(3)+2(ERA(4)+ERB(4))
CALB(2)=ERB(2)+CALA(3)+CALB(3)
=ERB(2)+ERA(3)+ERB(3)+2(ERA(4)+ERB(4))
=ERA(1)+CALA(2)+CALB(2)
=ERA(1)+ERA(2)+ERB(2)+2(ERA(3)+ERB(3))+4(ERA(4)+ERB(4))
CALB(1)=ERB(1)+CALA(2)+CALB(2)
=ERB(1)+ERA(2)+ERB(2)+2(ERA(3)+ERB(3))+4(ERA(4)+ERB(4))
wherein the calibration parameters of lower stages (I>6) are zero.

According to a second example of the calculating algorithms, i.e. a top-down algorithm, the output values of higher stages are assumed to be ideal values and the errors thereof are negligible. Hence, the calibration parameters can be derived using the following equations:
CALA(1)=0
CALB(1)=0
CALA(2)=Round(−ERA(1)/2)
CALB(2)=Round(−ERB(1)/2)
CALA(3)=Round(−ERA(1)/4−ERA(2)/2)
CALB(3)=Round(−ERB(1)/4−ERB(2)/2)
CALA(4)=Round(−ERA(1)/8−ERA(2)/4−ERA(3)/2)
CALB(4)=Round(−ERB(1)/8−ERB(2)/4−ERB(3)/2)
CALA(5)=Round(−ERA(1)/1 6−ERA(2)/8−ERA(3)/4−ERA(4)/2)
CALB(5)=Round(−ERB(1)/16−ERB(2)/8−ERB(3)/4−ERA(4)/2)
CALA(6)=Round(−ERA(1)/32−ERA(2)/16−ERA(3)/8−ERA(4)/4−ERA(5)/2)
CALB(6)=Round(−ERB(1)/32−ERB(2)/16−ERB(3)/8−ERA(4)/4-ERA(5)/2)
. . . . . .
wherein the function Round( . . . ) is a function for rounding up or down, and the calibration parameters of lower stages can be derived using similar principles.

According to a third example of the calculating algorithms, i.e. a middle-outward algorithm, the output value of a specific stage, e.g. the third stage, is assumed to be an ideal value and the error thereof is negligible. Therefore, the calibration parameters can be derived using the following equations:
CALA(1)=ERA(1)+ERA(2)+ERB(2)
CALB(1)=ERB(1)+ERA(2)+ERB(2)
CALA(2)=ERA(2)
CALB(2)=ERB(2)
CALA(3)=0
CALB(3)=0
CALA(4)=Round(−ERA(3)/2)
CALB(4)=Round(−ERB(3)/2)
CALA(5)=Round(−ERA(3)/4−ERA(4)/2)
CALB(5)=Round(−ERB(3)/4−ERB(4)/2)
CALA(6)=Round(−ERA(3)/8−ERA(4)/4−ERA(5)/2)
CALB(6)=Round(−ERB(3)/8−ERB(4)/4−ERB(5)/2)
. . . . . .
wherein the function Round( . . . ) is the function for rounding off, and the calibration parameters of lower stages can be derived using similar principles.

Note that there are still many possible algorithms for implementing the present invention. Those of ordinary skill in the art will understand that other algorithms for deriving the calibration parameters can be applied to the calculation unit 230 according to the present invention.

Operation of the calibration unit 220 is described as follows. After the calculation unit 230 generates the calibration parameters [CALA(I), CALB(I)] during the calibration mode, the calibration unit 220 generates each bit Dout_wiCal(I) of the digital output signal Dout_wiCal during the run mode according to the following descriptions (I=1, 2 . . . . . . , N):
if C(I)=−1, then Dout_wiCal(I)=D(I)-CALB(I)
if C(I)=0, then Dout_wiCal(I)=D(I)
if C(I)=+1, then Dout_wiCal(I)=D(I)+CALA(I)

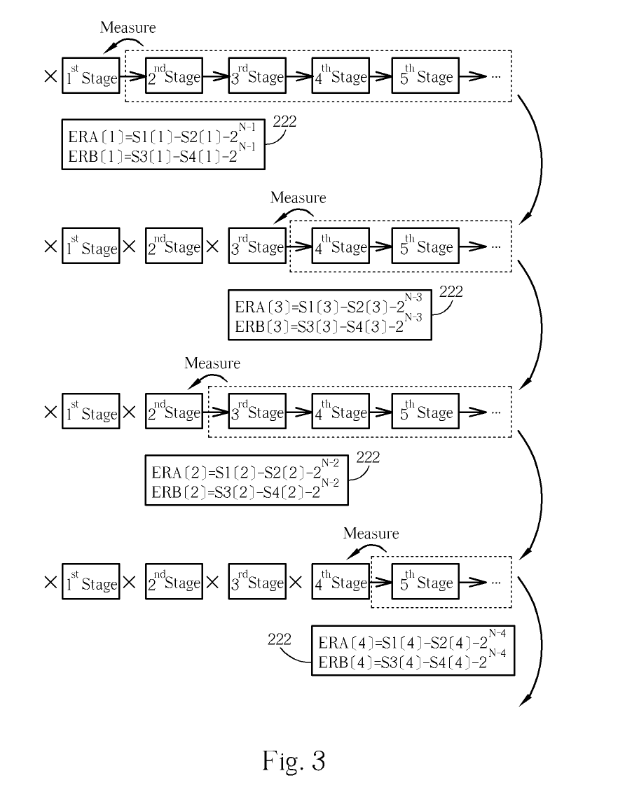

Hence, according to the embodiments mentioned above, those of ordinary skill in the art will understand that the digitally self-calibrating pipeline ADC 200 of the present invention can generate the intermediate error coefficients [ERA(J), ERB(J)] in any order and generate the calibration parameters [CALA(1), CALB(I)] according to the error coefficients [ERA(J), ERB(J)]. Please refer to FIG. 3, which illustrates an order for generating the intermediate error coefficients of the subsequent stages 114-1, 114-2 . . . . . . , and 114-N shown in FIG. 1. The order is independent of the arranged sequence of the subsequent stages 114-1, 114-2 . . . . . . , and 114-N. Consequently, the intermediate error coefficients [ERA(J), ERB(J)] can be generated in any order.

Those skilled in the art will readily observe that numerous modifications and alterations of the device may be made while retaining the teachings of the invention. Accordingly, the above disclosure should be construed as limited only by the metes and bounds of the appended claims.

1. A pipeline ADC for converting an analog input signal to a digital output signal comprising:
a plurality of analog-to-digital converting units cascading in series to form a pipeline;
a calculation unit for generating a plurality of calibration parameters according to signals outputted by the analog-to-digital converting units during a first mode; and
a calibration unit for correcting signals outputted by the analog-to-digital converting units during a second mode according to the calibration parameters, so as to generate the digital output signal.

2. The pipeline ADC of claim 1, wherein the calculation unit is capable of generating the calibration parameters in any order.

3. The pipeline ADC of claim 1, further comprising:
a plurality of switches, each of the switches coupled between two adjacent analog-to-digital converting units.

4. The pipeline ADC of claim 3, wherein one of the switches is controlled during the first mode such that a plurality of signals respectively having a fixed value are inputted into one of the analog-to-digital converting units.

5. The pipeline ADC of claim 3, wherein in the second mode, the switches are controlled during the second mode such that each of the analog-to-digital converting unit transmits signals to the next analog-to-digital converting unit.

6. The pipeline ADC of claim 1, wherein the calibration unit further comprises a memory for storing the calibration parameters.

7. The pipeline ADC of claim 1, wherein when generating the calibration parameters, the calculation unit is capable of assuming that the value of the signal outputted by any specific one of the analog-to-digital converting units is ideal during the second mode.

8. A method for self-calibrating a pipeline ADC comprising a plurality of analog-to-digital converting units cascading in series to form a pipeline, the method comprising the following steps:
reading output signals of the analog-to-digital converting units during a first mode;
generating a plurality of calibration parameters according to the output signals, wherein the calibration parameters are capable of being generated in any order; and
correcting output signals of the analog-to-digital converting units during a second mode according to the calibration parameters.

9. The method of claim 8 further comprising:
during the first mode, outputting a plurality of signals respectively having a fixed value to one of the analog-to-digital converting units.

10. The method of claim 8, wherein the step of generating the calibration parameters further comprises: assuming that the value of the signal outputted by any specific one of the analog-to-digital converting units is ideal during the second mode.
